(19) United States
(12) Patent Application Publication
(10) Pub. No.: US 2013/0027860 A1
(43) Pub. Date: Jan. 31, 2013

(54) Portable Information Display Terminal

(71) Applicant: Funai Electric Co., Ltd., Daito-shi (JP)

(72) Inventors: Yasuo MASAKI, Daito-shi (JP); Sei KOHNO, Daito-shi (JP)

(73) Assignee: Funai Electric Co., Ltd., Daito-shi (JP)

(21) Appl. No.: 13/645,011

(22) Filed: Oct. 4, 2012

Related U.S. Application Data
(63) Continuation of application No. PCT/IB2011/000946, filed on Apr. 4, 2011.

(30) Foreign Application Priority Data
Apr. 5, 2010 (JP) 2010-087186

(51) Int. Cl. H05K 7/00

(52) U.S. Cl. 361/679.01

(57) ABSTRACT

This portable information display terminal includes a liquid crystal display portion displaying information, a frame provided with the liquid crystal display portion on a surface thereof, an inclination sensor to detect at least the use state of the frame and the liquid crystal display portion by sensing an inclination of the frame, a camera unit capable of imaging the user's face, and a control portion detecting the orientation of the face with a face detection function on the basis of data of the user's face imaged by the camera unit and performing control of switching the orientation of a screen display of the liquid crystal display portion on the basis of a result of detection of the orientation of the face and a result of detection by the inclination sensor.

### CROSS-REFERENCE TO RELATED APPLICATIONS

This application is a continuation of PCT/IB2011/000946, Portable Information Display Terminal, Apr. 4, 2011, Yasuo Masaki and Sei Kohno.

### BACKGROUND OF THE INVENTION

1. Field of the Invention

The present invention relates to a portable information display terminal, and more particularly, it relates to a portable information display terminal including a display portion and a housing provided with the display portion.

2. Description of the Background Art

In general, a portable information display terminal including a display portion and a housing provided with the display portion is known, as disclosed in Japanese Patent Laying-Open No. 2009-130816, for example.

In the aforementioned Japanese Patent Laying-Open No. 2009-130816, there is disclosed a portable telephone (portable information display terminal) including a display portion displaying a television broadcast picture (screen display), a portable telephone body (housing) provided with the display portion on a surface thereof, and a camera (imaging portion) capable of imaging the user's face. This portable telephone according to Japanese Patent Laying-Open No. 2009-130816 is configured to image the user's face by the camera and display a television broadcast picture in a display direction corresponding to the orientation of the imaged user's face on the display portion when the user starts to watch the television broadcast picture on the display portion while grasping the portable telephone body.

In the portable telephone (portable information display terminal) according to the aforementioned Japanese Patent Laying-Open No. 2009-130816, however, the orientation of the user's face cannot be detected when the user's face cannot be imaged by the camera, such as when the user is absent in the imaging range of the camera. Therefore, in the aforementioned Japanese Patent Laying-Open No. 2009-130816, there is such a problem that the television broadcast picture (screen display) cannot be displayed in the suitable display direction corresponding to the orientation of the user's face on the display portion when the orientation of the user's face cannot be detected.

### SUMMARY OF THE INVENTION

The present invention has been proposed in order to solve the aforementioned problem, and an object of the present invention is to provide a portable information display terminal capable of displaying a screen in a suitable display orientation also in a case where the orientation of the user's face cannot be detected.

A portable information display terminal according to an aspect of the present invention includes a display portion displaying information, a housing provided with the display portion on a surface thereof, a state detection sensor to detect at least the use state of the housing and the display portion by sensing an inclination of the housing, an imaging portion capable of imaging the user's face, and a control portion detecting the orientation of the face with a face detection function on the basis of data of the user's face imaged by the imaging portion and performing control of switching the orientation of a screen display of the display portion on the basis of a result of detection of the orientation of the face and a result of detection by the state detection sensor.

In this portable information display terminal according to the aspect, as hereinabove described, the orientation of the screen display of the display portion is switched on the basis of the result of detection of the orientation of the user's face detected with the face detection function and the result of detection by the state detection sensor, whereby which state (attitude) the housing is in can be detected by the state detection sensor sensing the inclination of the housing also in a case where the orientation of the user's face imaged by the imaging portion cannot be detected, dissimilarly to a case where the orientation of the screen display of the display portion is switched on the basis of only the result of detection of the orientation of the user's face detected with the face detection function. Thus, the screen can be displayed in a suitable display orientation on the basis of the state (attitude) detected by the state detection sensor also in the case where the orientation of the user's face imaged by the imaging portion cannot be detected.

Preferably in the aforementioned portable information display terminal according to the aspect, the control portion is configured to prioritize the result of detection of the orientation of the user's face over the use state detected by the state detection sensor and switch the orientation of the screen display to one corresponding to the orientation of the user's face in a case where the state detection sensor detects a prescribed use state. When configuring the portable information display terminal in this manner, the result of detection of the orientation of the user's face is prioritized in the case of the prescribed use state where the orientation of the screen display based on the result of detection of the orientation of the user's face and the orientation of the screen display based on the inclination detected by the state detection sensor easily differ from each other, so that the screen display can be displayed in an orientation more suitable to an actual use mode.

Preferably in the aforementioned portable information display terminal switching the orientation of the screen display to one corresponding to the orientation of the user's face in the case of detecting the prescribed use state, the prescribed use state is a use state where the user uses the portable information display terminal while grasping the housing with his/her hand, and the control portion is configured to prioritize the result of detection of the orientation of the user's face over the use state detected by the state detection sensor and switch the orientation of the screen display to one corresponding to the orientation of the user's face in a case where the use state where the user uses the portable information display terminal while grasping the housing with his/her hand is detected. When configuring the portable information display terminal in this manner, it is difficult to determine how the user sees the screen from the detection result based on the inclination detected by the state detection sensor in a case where the user uses the portable information display terminal while lying down in the state where the user grasps the housing with his/her hand so that the screen display can be displayed in an orientation more suitable to an actual use mode by detecting the orientation of the user's face and switching the orientation of the screen display to one corresponding to the orientation of the user's face in the case where the portable information display terminal is in the state where the user grasps the housing with his/her hand.

Preferably in this case, the control portion is configured to perform control of switching the orientation of the screen display of the display portion on the basis of the result of detection by the state detection sensor in a case where the state detection sensor detects that the portable information display terminal is not in the use state where the user uses the portable information display terminal while grasping the housing with his/her hand. In the case where the state detection sensor detects that the user does not grasp the housing with his/her hand as just described, the housing is conceivably fixedly placed on a placing surface or the like. In a case where the housing is fixedly placed on the placing surface or the like, the orientation of the display portion and the orientation of the user's face when the user sees the display portion satisfy a specific relationship, and the user's face can be detected less often than the case where the user uses the portable information display terminal while grasping the housing with his/her hand. Thus, in this case, the control of switching the orientation of the screen display of the display portion is performed with the result of detection by the state detection sensor without using the face detection function, whereby the screen can be displayed in a suitable display orientation.

Preferably in the aforementioned portable information display terminal switching the orientation of the screen display to one corresponding to the orientation of the user's face in the case of detecting the prescribed use state, the state detection sensor is provided to detect which use state of a first use state where the user uses the portable information display terminal while standing the housing and the display portion on the placing surface, a second use state where the user uses the portable information display terminal while laying down the housing and the display portion on the placing surface, and a third use state where the user uses the portable information display terminal while grasping the housing with his/her hand as the prescribed use state the portable information display terminal is in by sensing the inclination of the housing, and the control portion is configured to perform control of prioritizing the result of detection of the orientation of the user's face and switching the orientation of the screen display to one corresponding to the orientation of the user's face in a case where the state detection sensor detects that the portable information display terminal is at least in the third use state, and to perform control of switching the orientation of the screen display of the display portion on the basis of the result of detection by the state detection sensor in a case where the state detection sensor detects that the portable information display terminal is in the first use state or the second use state. When configuring the portable information display terminal in this manner, the screen can be displayed in a suitable display orientation by the state detection sensor in the case where the portable information display terminal is in the first use state or the second use state where the housing is placed on the placing surface. Furthermore, the screen can be displayed in a suitable display orientation matching the orientation of the user's face on the basis of the result of detection of the orientation of the user's face in the case where the portable information display terminal is in the third use state where the user uses the portable information display terminal while grasping the housing with his/her hand.

Preferably in the aforementioned portable information display terminal switching the orientation of the screen display to one corresponding to the orientation of the user's face in the case of detecting the prescribed use state, the state detection sensor is configured to detect at least an unused state turning down the portable information display terminal so that the display portion is opposed to the placing surface in addition to the prescribed use state, and the control portion is configured to perform control of shifting to a standby mode without using the face detection function in a case where the state detection sensor detects that the portable information display terminal is not in the prescribed use state where the housing is grasped by the user and detects an inclination of the housing in the unused state turning down the portable information display terminal so that the display portion is opposed to the placing surface, and to perform control of not shifting to the standby mode but displaying a screen display based on the result of detection of the orientation of the user's face on the display portion in a case where the state detection sensor detects that the portable information display terminal is in the prescribed use state where the housing is grasped by the user and detects the inclination of the housing in the unused state turning down the portable information display terminal so that the display portion is opposed to the placing surface. When configuring the portable information display terminal in this manner, it is considered that the user does not use the portable information display terminal in the case where the state detection sensor detects that the portable information display terminal is not in the prescribed use state where the housing is grasped by the user and detects the inclination of the housing in the unused state turning down the portable information display terminal so that the display portion is opposed to the placing surface. Thus, in this case, the portable information display terminal shifts to the standby mode so that power consumption of the portable information display terminal can be reduced. On the other hand, it is considered that the user uses the portable information display terminal (sees the display portion while lying on his/her back, for example) in the case where the state detection sensor detects that the housing is grasped by the user even when detecting the inclination of the housing in the unused state turning down the portable information display terminal so that the display portion is opposed to the placing surface, and hence in this case, the screen can be displayed in a suitable display orientation matching the orientation of the user's face on the basis of the result of detection of the orientation of the user's face.

Preferably in the aforementioned portable information display terminal switching the orientation of the screen display to one corresponding to the orientation of the user's face in the case of detecting the prescribed use state, the state detection sensor is provided to detect which use state of a first use state where the user uses the portable information display terminal while standing at least the housing and the display portion on the placing surface, a second use state where the user uses the portable information display terminal while laying down the housing and the display portion on the placing surface, and a third use state where the user uses the portable information display terminal while grasping the housing with his/her hand as the prescribed use state the portable information display terminal is in by sensing the inclination of the housing, and the housing is configured to have an outer shape settable on the placing surface so that a first inclination of the housing in the first use state and a second inclination of the housing in the second use state become inclinations different from each other. When configuring the portable information display terminal in this manner, the housing can be set on the placing surface at different inclinations in the first use state and the second use state on the basis of the outer shape of the housing. Thus, the first use state and the second use state can be easily determined and specified on the basis of the result of detection by the state detection sensor, and the screen can be displayed in a suitable display orientation corresponding to the first use state or the second use state.

Preferably in the aforementioned portable information display terminal according to the aspect, the control portion is configured to maintain the orientation of the screen display of the display portion unswitched if determining that an inclination value detected this time by the state detection sensor falls within a prescribed angular range from an inclination value previously detected by the state detection sensor in a case where the orientation of the user's face cannot be detected from the data of the user's face imaged by the imaging portion when the state detection sensor detects the use state where the user uses the portable information display terminal while grasping the housing with his/her hand. When configuring the portable information display terminal in this manner, the inclination value detected this time by the state detection sensor has not been significantly changed from the inclination value previously detected by the state detection sensor in the case where the inclination value detected this time by the state detection sensor falls within the prescribed angular range from the inclination value previously detected by the state detection sensor in the state where the user grasps the housing, and hence it is considered that a relative positional relationship between the user and the portable information display terminal has not been significantly changed. In this case, the orientation of the screen display of the display portion is not switched but maintained, whereby the screen can be displayed in a suitable display orientation matching the orientation of the user's face.

Preferably in this case, the control portion is configured to detect the orientation of the user's face again with the face detection function if it is detected that the inclination value detected this time by the state detection sensor has been changed over the prescribed angular range from the inclination value previously detected by the state detection sensor in the case where the orientation of the user's face cannot be detected from the data of the user's face imaged by the imaging portion. When configuring the portable information display terminal in this manner, the inclination value detected this time by the state detection sensor has been significantly changed from the inclination value previously detected by the state detection sensor in the case where the inclination value detected this time by the state detection sensor has been changed over the prescribed angular range from the inclination value previously detected by the state detection sensor in the state where the user grasps the housing, and hence it is considered that the relative positional relationship between the user and the portable information display terminal has been significantly changed or the way the user holds the housing has been changed. In this case, the orientation of the user's face is detected again with the face detection function, whereby the screen can be displayed in a suitable display orientation matching the orientation of the user's face on the basis of a result of detection of the redetected orientation of the user's face.

Preferably in the aforementioned portable information display terminal according to the aspect, the state detection sensor includes an inclination sensor. When configuring the portable information display terminal in this manner, the inclination of the housing can be easily detected by the inclination sensor.

### BRIEF DESCRIPTION OF THE DRAWINGS

FIG. 1 is an overall perspective view for illustrating the structure on a liquid crystal display portion side of a portable information display terminal according to an embodiment of the present invention;

FIG. 2 is an overall perspective view for illustrating the structure on a surface side of a frame of the portable information display terminal shown in FIG. 1 opposite to a surface provided with a liquid crystal display portion;

FIG. 3 is a perspective view showing a state where the portable information display terminal is grasped while laterally orienting the longitudinal direction of the portable information display terminal shown in FIG. 1;

FIG. 4 is a perspective view showing a state where the portable information display terminal is grasped while vertically orienting the longitudinal direction of the portable information display terminal shown in FIG. 1;

FIG. 5 is a perspective view showing a state standing the frame and the liquid crystal display portion of the portable information display terminal shown in FIG. 1 on a placing surface;

FIG. 6 is a perspective view showing a state laying down the frame and the liquid crystal display portion of the portable information display terminal shown in FIG. 1 on the placing surface;

FIG. 7 is a block diagram for illustrating the internal structure of the portable information display terminal shown in FIG. 1;

FIG. 8 is a perspective view showing an unused state where the frame and the liquid crystal display portion of the portable information display terminal shown in FIG. 1 are turned down with respect to the placing surface;

FIG. 9 is a perspective view showing a state where the short-side direction of the liquid crystal display portion of the portable information display terminal shown in FIG. 1 and the vertical direction of the user's face substantially coincide with each other;

FIG. 10 is a diagram showing a state where the orientation of the user's face is inclined between about −45° and about +45° with respect to the short-side direction of the liquid crystal display portion of the portable information display terminal shown in FIG. 1;

FIG. 11 is a perspective view showing a state where the longitudinal direction of the liquid crystal display portion of the portable information display terminal shown in FIG. 1 and the vertical direction of the user's face substantially coincide with each other;

FIG. 12 is a diagram showing a state where the orientation of the user's face is inclined between about −45° and about +45° with respect to the longitudinal direction of the liquid crystal display portion of the portable information display terminal shown in FIG. 1;

FIG. 13 is a flow chart for illustrating a flow for change and maintenance of a display orientation corresponding to the state (state other than the hand-held state) of the portable information display terminal shown in FIG. 1; and

FIG. 14 is a flow chart for illustrating a flow for change and maintenance of a display orientation corresponding to the state (hand-held state) of the portable information display terminal shown in FIG. 1.

### DESCRIPTION OF THE PREFERRED EMBODIMENTS

An embodiment embodying the present invention is now described on the basis of the drawings.

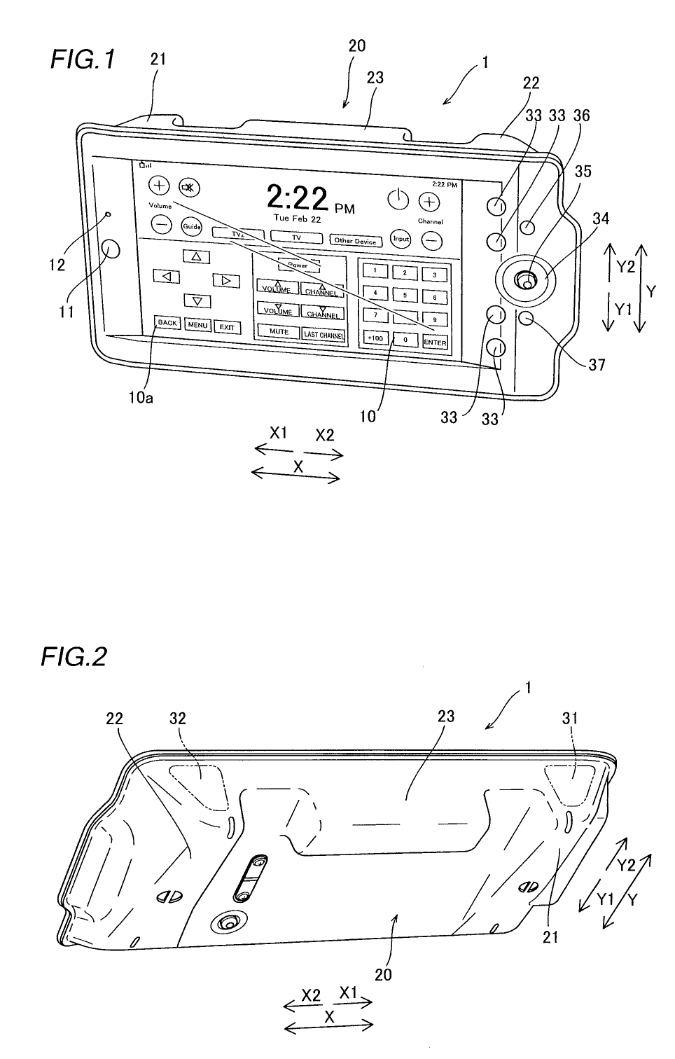

First, the structure of a portable information display terminal 1 according to the embodiment of the present invention is described with reference to FIGS. 1 to 12.

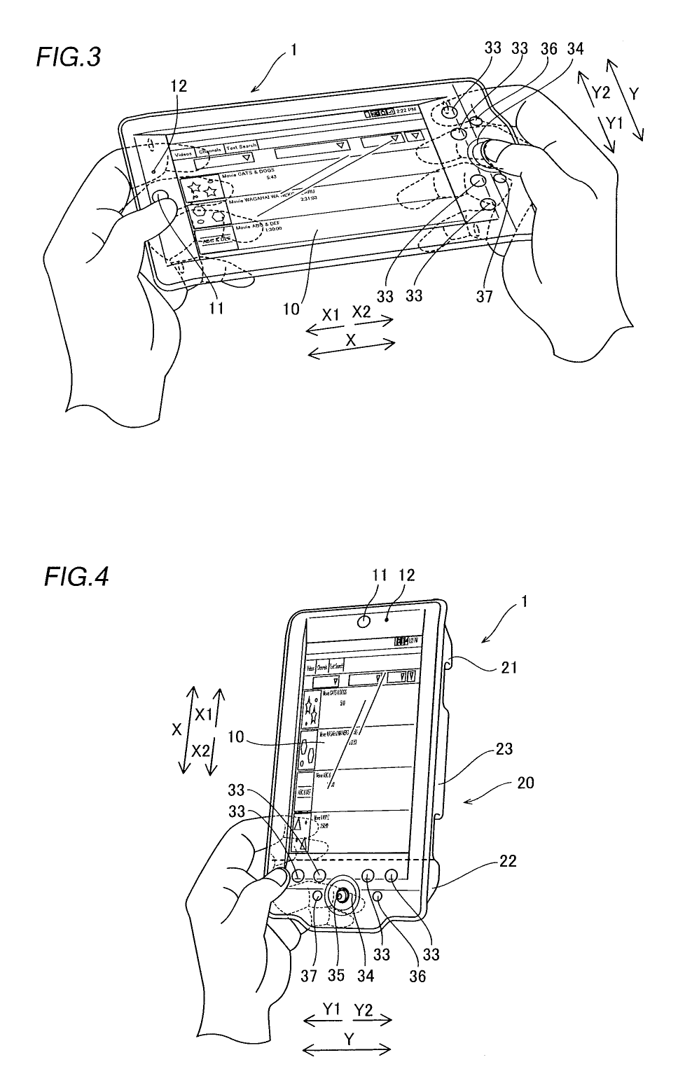

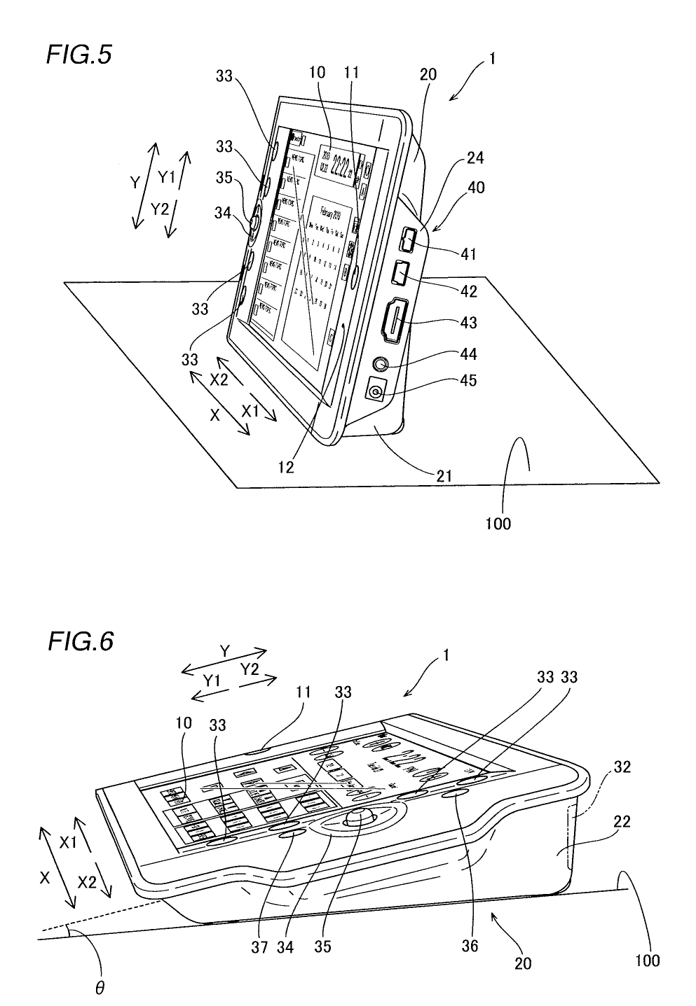

As shown in FIGS. 1 and 2, the portable information display terminal 1 according to the embodiment of the present invention is mainly constituted by a liquid crystal display portion 10 (see FIG. 1) displaying information and a frame 20 provided with the liquid crystal display portion 10 on a surface thereof. The liquid crystal display portion 10 is an example of the “display portion” in the present invention, and the frame 20 is an example of the “housing” in the present invention. This portable information display terminal 1 is configured to be usable in a state (see FIGS. 3 and 4) grasped by the user, and to be usable also in a state (see FIG. 5) standing the frame 20 and the liquid crystal display portion 10 on a placing surface 100 and a state (see FIG. 6) laying down the frame 20 and the liquid crystal display portion 10 on the placing surface 100. The state grasped by the user is an example of the “prescribed use state” or the “third use state” in the present invention, and the state standing the frame 20 and the liquid crystal display portion 10 on the placing surface 100 is an example of the “first use state” in the present invention. The state laying down the frame 20 and the liquid crystal display portion 10 on the placing surface 100 is an example of the “second use state” in the present invention.

This portable information display terminal 1 is configured to be Internet-connectable, and configured to be capable of using a function of receiving and playing back/outputting streaming distributions, an electronic mail function, a video chat function, and a voice chat function by performing Internet connection. Furthermore, the portable information display terminal 1 is configured to be usable as a remote control for a media player, a television set (not shown), etc. by shifting to a remote control mode also in a case where the same is not Internet-connected. The portable information display terminal 1 is capable of displaying a calendar, a clock, etc. by small-scale application software (gadget) in the state (see FIG. 5) standing the frame 20 and the liquid crystal display portion 10.

The structures of the liquid crystal display portion 10 and the frame 20 of the portable information display terminal 1 are now described in detail. The liquid crystal display portion 10 has a touch panel function, as shown in FIG. 1, and is so configured that the user presses down operation buttons 10a displayed on the liquid crystal display portion 10 to be capable of operations according to application programs. A camera unit 11 is set on an arrow X1 direction side of the liquid crystal display portion 10. This camera unit 11 has a function of imaging the user's face in a case where the user uses the portable information display terminal 1 in a state grasped by the user, for example. The camera unit 11 is an example of the “imaging portion” in the present invention.

A microphone unit 12 is set in the vicinity of the camera unit 11. This microphone unit 12 has a function of inputting sounds in the voice chat, the video chat, etc., for example.

The frame 20 is made of resin. As shown in FIGS. 1 and 2, a plurality of protrusions 21, 22, and 23 are integrally provided on a surface of the frame 20 opposite to the surface provided with the liquid crystal display portion 10. The protrusions 21 and 22 are provided in the vicinity of both end portions in the longitudinal direction (direction X) of the frame 20 to extend in the short-side direction (direction Y) of the frame 20. As shown in FIG. 6, the protrusions 21 (see FIG. 2) and 22 are so configured that the thicknesses gradually increase from a first end side (arrow Y1 direction side) toward a second end side (arrow Y2 direction side) in the short-side direction (direction Y) of the frame 20. In other words, the protrusions 21 and 22 are configured to have wedge shapes tapering in a tapering manner from the second side (arrow Y2 direction side) toward the first side (arrow Y1 direction side) in the short-side direction of the frame 20, as viewed from the longitudinal direction (the arrow X1 direction and the arrow X2 direction) of the frame 20.

The protrusions 21 and 22 are so configured in the aforementioned manner that the user places the portable information display terminal 1 on the placing surface 100 while directing surfaces of the protrusion 21 and the protrusion 22 on the arrow Y2 direction sides downward, whereby the protrusions 21 and 22 are capable of supporting the frame 20 in a state standing the frame 20 and the liquid crystal display portion 10, as shown in FIG. 5. Furthermore, the protrusions 21 (see FIG. 2) and 22 are capable of supporting the frame 20 in a state inclining the frame 20 and the liquid crystal display portion 10 by a prescribed angle θ and laying down the same with respect to the placing surface 100, as shown in FIG. 6.

In addition, the protrusions 21 and 22 are so configured in the aforementioned manner that the user can grasp the protrusions 21 and 22 with both hands while laterally orienting the longitudinal direction (direction X) of the frame 20 and the liquid crystal display portion 10 as viewed from the user, as shown in FIG. 3. As shown in FIG. 4, the protrusion 22 is graspable with one hand (left hand) while vertically orienting the longitudinal direction (direction X) of the frame 20 and the liquid crystal display portion 10.

The protrusion 23 is provided in the vicinity of a second end portion (arrow Y2 direction end portion) in the short-side direction (direction Y) of the frame 20 between the protrusions 21 and 22, as shown in FIG. 2. A secondary cell (lithium ion cell) to supply power to the portable information display terminal 1 is built (stored) in this protrusion 23.

Infrared communication portions 31 and 32 are built in end surfaces of the protrusions 21 and 22 on second end portion sides (arrow Y2 direction sides), respectively. These infrared communication portions 31 and 32 are configured to emit infrared rays including prescribed signals (remote control signals) capable of operating the media player, the television set (not shown), etc. in a remote control mode described later.

Various types of information processor mode switches 33 are provided on portions on an arrow X2 direction side in the longitudinal direction (direction X) of the liquid crystal display portion 10, as shown in FIG. 1. The various types of information processor mode switches 33 are switches used in an information processor mode processing an electronic mail, video, voice chats, and the like, respectively. A four-directional movable switch 34 (selection switch) is provided in the vicinity of the various types of information processor mode switches 33 on the arrow X2 direction side. A decision switch 35 is provided on a central portion of the four-directional movable switch 34. The four-directional movable switch 34 and the decision switch 35 each are configured to be usable in both of the remote control mode and the information processor mode.

A remote control mode transition switch 36 capable of switching the remote control mode and the information processor mode is provided on the arrow Y2 direction side of the four-directional movable switch 34. A return function switch 37 to return an operation screen OSD-displayed on a display portion of a remote control operation object apparatus (television or the like) in the remote control mode from the current state to an immediately precedent state is provided on the arrow Y1 direction side of the four-directional movable switch 34.

As shown in FIG. 5, a plurality of connection portions 40 are provided on a side surface portion 24 on the arrow X1 direction side of the frame 20. These connection portions 40 include two USB connection portions 41 and 42, an HDMI connection portion 43, a voice cable connection portion 44, and a power supply connector 45.

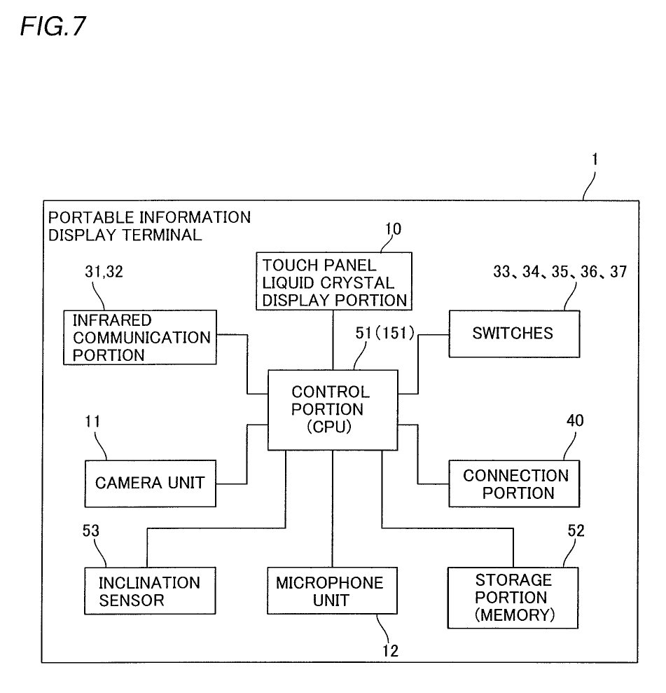

The internal structure of the portable information display terminal 1 is now described. The frame 20 of the portable information display terminal 1 is provided with a control portion (CPU) 51 managing control of the portable information display terminal 1, a storage portion (memory) 52, and an inclination sensor 53, as shown in FIG. 7. The storage portion 52 stores application programs executed by the control portion 51. The inclination sensor 53 is an example of the “state detection sensor” in the present invention.

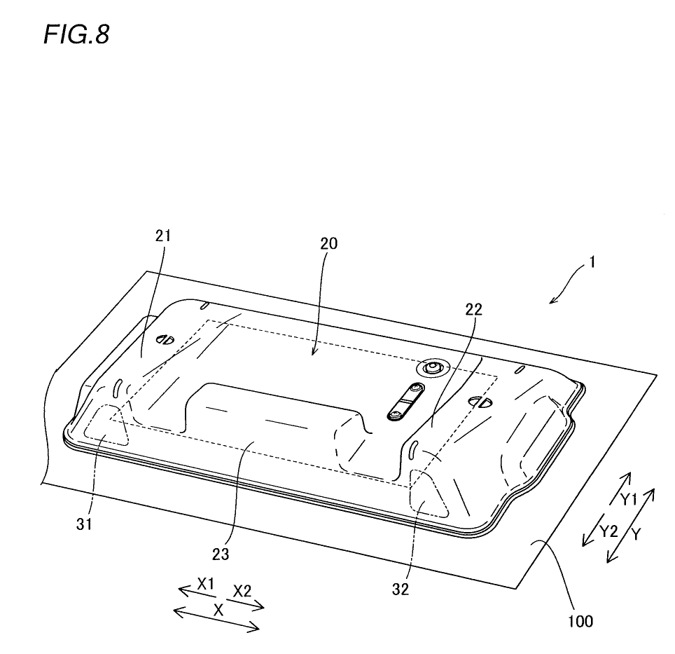

According to this embodiment, the inclination sensor 53 has a function of acquiring an inclination of the frame 20 (see FIG. 1). The inclination sensor 53 is provided to detect which use state the portable information display terminal 1 is in, i.e. in a state (hereinafter referred to as a stood state (see FIG. 5)) where the user uses the portable information display terminal 1 while standing the frame 20 and the liquid crystal display portion 10 on the placing surface 100, in a state (hereinafter referred to as a laid-down state (see FIG. 6)) where the user uses the portable information display terminal 1 while laying down the frame 20 and the liquid crystal display portion 10 on the placing surface 100, or in a state (hereinafter referred to as a hand-held state (see FIGS. 3 and 4)) where the user uses the portable information display terminal 1 while grasping the frame 20 with his/her hand. The inclination sensor 53 is configured to be capable of detecting not only the stood state (see FIG. 5), the laid-down state (see FIG. 6), and the hand-held state (see FIGS. 3 and 4) but also an unused state (see FIG. 8) turning down the portable information display terminal 1 so that the frame 20 and the liquid crystal display portion 10 are opposed to the placing surface 100.

As to an inclination in the stood state (see FIG. 5), an inclination in the laid-down state (see FIG. 6), and an inclination in the turned-down unused state (see FIG. 8), angles of the frame 20 with respect to the placing surface 100 are different from each other by at least 90 degrees due to the aforementioned outer shape of the frame 20, and hence the control portion 51 is capable of easily detecting and specifying the respective states on the basis of the different inclinations of the frame 20 with respect to the placing surface 100. The inclination in the state where the user uses the portable information display terminal 1 while standing the frame 20 and the liquid crystal display portion 10 on the placing surface 100 is an example of the “first inclination” in the present invention, and the inclination in the state where the user uses the portable information display terminal 1 while laying down the frame 20 and the liquid crystal display portion 10 on the placing surface 100 is an example of the “second inclination” in the present invention.

In the hand-held state (see FIGS. 3 and 4), a detection value detected by the inclination sensor 53 changes every detection time due to the fact that the user finely moves, and hence the control portion 51 is enabled to distinguish the stood state, the laid-down state, and the unused state from the hand-held state. Furthermore, the inclination sensor 53 is configured to be capable of detecting a vertically oriented use state (hereinafter referred to as a vertically held state (see FIG. 4)) where the user uses the portable information display terminal 1 while vertically orienting the longitudinal direction of the frame 20 and a laterally oriented use state (hereinafter referred to a laterally held state (see FIG. 3)) where the user uses the portable information display terminal 1 while laterally orienting the longitudinal direction of the frame 20 also in a case where the portable information display terminal 1 is in the hand-held state (see FIGS. 3 and 4). In the vertically held state and the laterally held state, the liquid crystal display portion 10 is rotated by about 90 degrees as shown in FIGS. 3 and 4, whereby the inclination sensor 53 is capable of easily determining and specifying different inclinations in the vertically held state and the laterally held state.

According to this embodiment, the control portion 51 is configured to determine and specify the use state or the unused state of the frame 20 and the liquid crystal display portion 10 on the basis of a result of detection of the use state or the unused state of the frame 20 and the liquid crystal display portion 10 by the inclination sensor 53 and a result of detection of the orientation of the user's face detected by the face detection function of the camera unit 11. Furthermore, the control portion 51 is configured to perform control of switching the orientation of the screen display of the liquid crystal display portion 10 on the basis of the aforementioned result of detection by the inclination sensor 53 and the aforementioned result of detection of the orientation of the user's face.

More specifically, the control portion 51 is configured to determine and specify which state the portable information display terminal 1 is in, i.e. in the stood state (see FIG. 5), in the laid-down state (see FIG. 6), in the hand-held state (see FIGS. 3 and 4), or in the unused state (see FIG. 8) on the basis of the result of detection by the inclination sensor 53 when the user changes the attitude (state) of the portable information display terminal 1. Furthermore, the control portion 51 is configured to switch the orientation of the screen display of the liquid crystal display portion 10 to correspond to the stood state (see FIG. 5) or the laid-down state (see FIG. 6) on the basis of the result of detection by the inclination sensor 53 in a case of determining and specifying that the portable information display terminal 1 is in the stood state (see FIG. 5) or in the laid-down state (see FIG. 6) on the basis of the result of detection by the inclination sensor 53. In other words, the control portion 51 is configured to perform control of switching the orientation of the screen display of the liquid crystal display portion 10 on the basis of the result of detection by the inclination sensor 53 in a case where the inclination sensor 53 detects that the portable information display terminal 1 is not in the hand-held state, when the user changes the attitude (state) of the portable information display terminal 1.

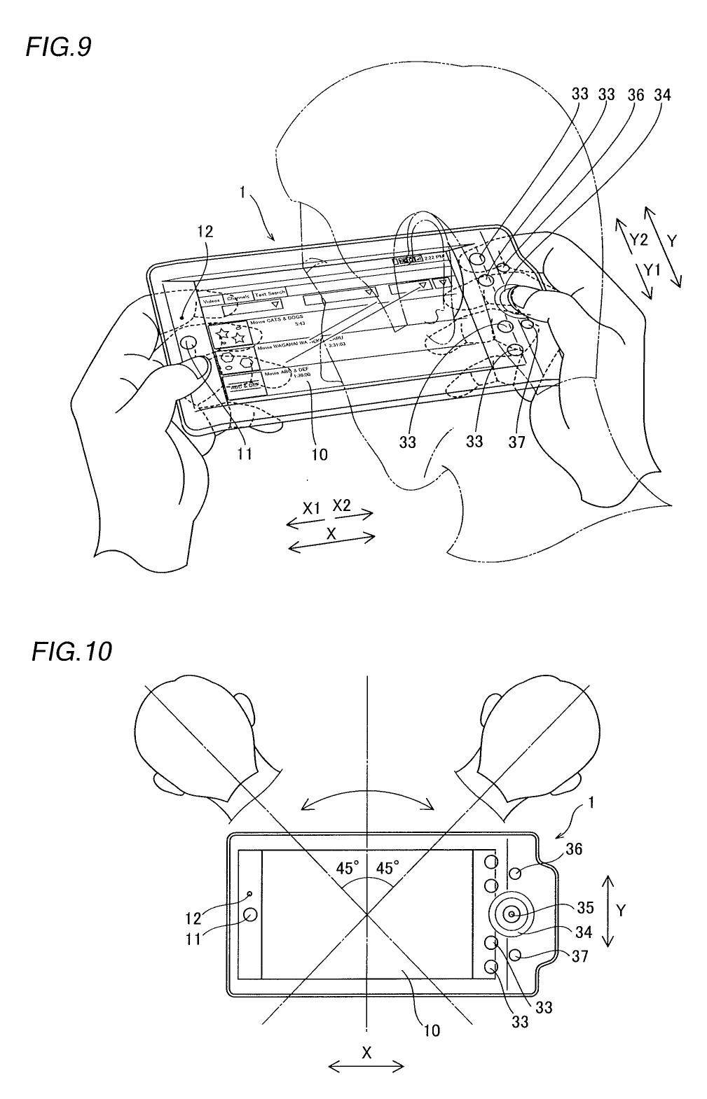

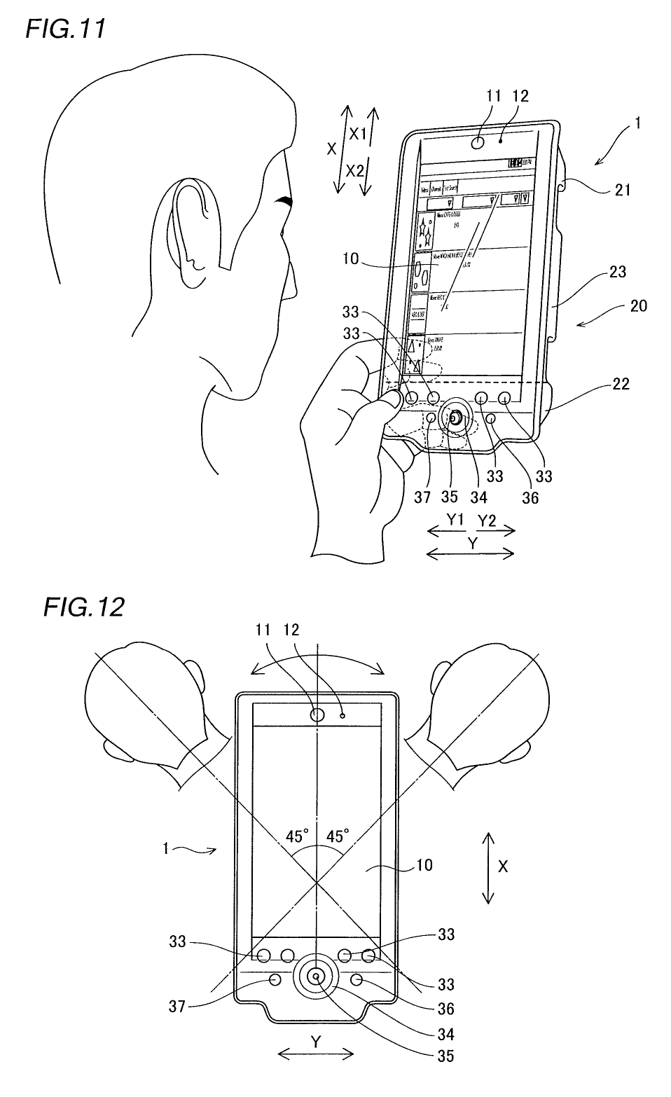

In addition, the control portion 51 is configured to prioritize the result of detection of the orientation of the user's face over the hand-held state detected by the inclination sensor 53 and switch the orientation of the screen display to one corresponding to the orientation of the user's face in a case of determining and specifying that the portable information display terminal 1 is in the hand-held state (see FIGS. 3 and 4) on the basis of the result of detection by the inclination sensor 53. More specifically, the control portion 51 has a function of detecting the orientation of the user's face imaged by the camera unit 11 with the face detection function, and is configured to display the screen display, setting the short-side direction (direction Y) of the liquid crystal display portion 10 as the vertical direction in a case of determining that the vertical direction of the user's face is an orientation substantially coinciding with the short-side direction (direction Y) of the liquid crystal display portion 10, as shown in FIGS. 9 and 10. The control portion 51 is configured to display the screen display, setting the short-side direction (direction Y) of the liquid crystal display portion 10 as the vertical direction in a case where the orientation of the user's face is inclined between about −45° and about +45° (see FIG. 10) with respect to the short-side direction (direction Y) of the liquid crystal display portion 10 in this case. Furthermore, the control portion 51 is configured to display the screen display, setting the longitudinal direction (direction X) of the liquid crystal display portion 10 as the vertical direction in a case of determining that the vertical direction of the user's face is an orientation substantially coinciding with the longitudinal direction (direction X) of the liquid crystal display portion 10, as shown in FIGS. 11 and 12. In addition, the control portion 51 is configured to display the screen display, setting the longitudinal direction (direction X) of the liquid crystal display portion 10 as the vertical direction in a case where the orientation of the user's face is inclined between about −45° and about +45° (see FIG. 12) with respect to the longitudinal direction (direction X) of the liquid crystal display portion 10.

The control portion 51 is configured to perform control of automatically starting an application program corresponding to the specified use state or shifting to a standby mode. More specifically, the control portion 51 is configured to start an application program not premised to be operated by the user in a case of specifying that the portable information display terminal 1 is in the stood state (see FIG. 5). In addition, the control portion 51 is configured to start an application program premised to be operated by the user in a case of specifying that the portable information display terminal 1 is in the laid-down state (see FIG. 6). Furthermore, the control portion 51 is configured to start the application program premised to be operated by the user also in a case of specifying that the portable information display terminal 1 is in the hand-held state (see FIGS. 3 and 4). The application program corresponding to the specified use state is preset by the user.

The control portion 51 is configured to determine which state the portable information display terminal 1 is in, i.e. in the state (state of FIGS. 5, 6, and 8) placed on the placing surface 100 or in the state (state of FIGS. 3 and 4) grasped by the user by determining whether or not the inclination value detected by the inclination sensor 53 regularly changes piecemeal. The control portion 51 is configured to determine that the portable information display terminal 1 is in the state grasped by the user in the case where the inclination value detected by the inclination sensor 53 regularly changes piecemeal. Furthermore, the control portion 51 is configured to determine that the portable information display terminal 1 is in the state placed on the placing surface 100 in a case where the inclination value detected by the inclination sensor 53 is stable.

According to this embodiment, the control portion 51 is configured to perform control of shifting to the standby mode in a case of specifying that the portable information display terminal 1 is in the unused state (see FIG. 8) turning down the portable information display terminal 1 so that the frame 20 and the liquid crystal display portion 10 are opposed to the placing surface 100 with the inclination sensor 53. The control portion 51 is configured not to start any application program used by the user in this case, dissimilarly to the time of the use state (the stood state, the laid-down state, or the hand-held state).

According to this embodiment, the control portion 51 is configured not to shift to the standby mode even if an inclination value similar to that in the unused state (see FIG. 8) is detected in a case where an inclination value in the hand-held state is detected by the inclination sensor 53. The control portion 51 is configured to perform control of displaying a screen display based on the result of detection of the orientation of the user's face on the liquid crystal display portion 10 in this case. In other words, the control portion 51 is configured to perform control of suppressing the shift to the standby mode in whatever state the frame 20 is in when the user grasps the frame 20.

Next, a flow for change and maintenance of a display orientation corresponding to the state of the portable information display terminal 1 according to this embodiment is described with reference to FIGS. 3 to 8, 13, and 14.

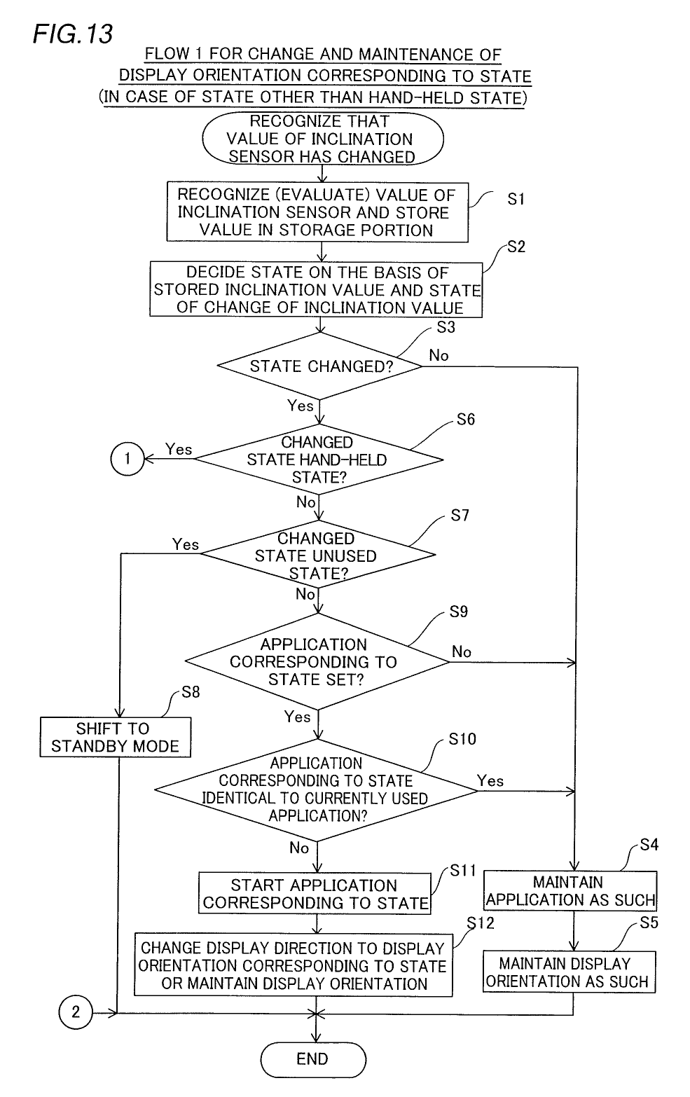

As shown in FIG. 13, the control portion 51 recognizes that the inclination value acquired by the inclination sensor 53 has changed (event occurrence), whereby the starting flow for the application program corresponding to the use state of the portable information display terminal 1 is started. First, the inclination value acquired from the inclination sensor 53 is recognized (evaluated) by the control portion 51 (see FIG. 7), and the inclination value is stored in the storage portion 52 at a step S1. At a step S2, which state of the stood state (see FIG. 5), the laid-down state (see FIG. 6), the unused state (see FIG. 8), and the hand-held state (see FIGS. 3 and 4) the portable information display terminal 1 is in is determined on the basis of states of change of a stored past inclination value and the inclination value stored this time. In other words, the portable information display terminal 1 is decided to be in the hand-held state in a case where the stored past inclination value and the inclination value stored this time change piecemeal. Furthermore, the portable information display terminal 1 is decided to be in the stood state in a case where the stored past inclination value and the inclination value stored this time do not change piecemeal but the inclination value stored this time is in the range of the inclination value in the stood state, the portable information display terminal 1 is decided to be in the laid-down state in a case where the inclination value stored this time is in the range of the inclination value in the laid-down state, and the portable information display terminal 1 is decided to be in the unused state in a case where the inclination value stored this time is in the range of the inclination value in the turned-down unused state.

Thereafter, whether or not the decided state has been changed from a state (before event occurrence) before the inclination value acquired by the inclination sensor 53 changes is determined by the control portion 51 at a step S3. In a case where it is determined at the step S3 that the decided state has not been changed from the state (before event occurrence) before the inclination value acquired by the inclination sensor 53 changes, the control portion 51 advances to a step S4. The state has not been changed, and hence the application program is not changed but the application program is maintained as such at the step S4, and the control portion 51 advances to a step S5. The display orientation displayed on the liquid crystal display portion 10 is not changed either but maintained as such at the step S5, and the flow for change and maintenance of a display orientation corresponding to the state of the portable information display terminal 1 terminates.

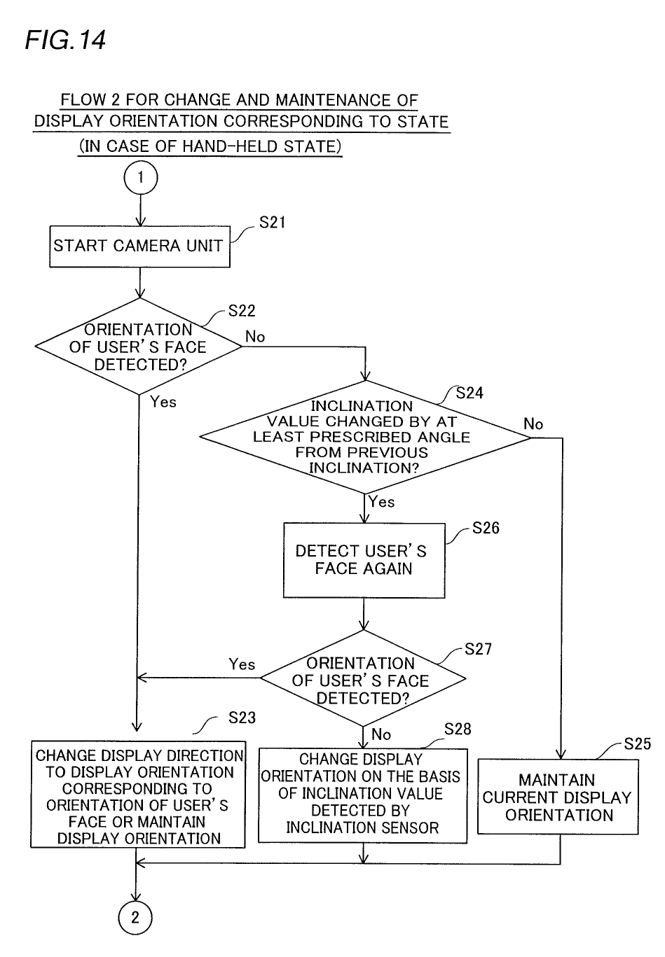

In a case where it is determined at the step S3 that the decided state has been changed from the state (before event occurrence) before the inclination value acquired by the inclination sensor 53 changes, the control portion 51 advances to a step S6. At the step S6, whether or not the changed state is the state (hand-held state (see FIGS. 3 and 4)) where the user uses the portable information display terminal 1 while grasping the frame 20 with his/her hand is determined by the control portion 51. In a case where it is determined at the step S6 that the changed state is the hand-held state, the control portion 51 advances to a step S21 (see FIG. 14) described later. In a case where it is determined at the step S6 that the changed state is not the hand-held state, the control portion 51 advances to a step S7.

At the step S7, whether or not the changed state is the unused state (see FIG. 8) turning down the portable information display terminal 1 so that the frame 20 and the liquid crystal display portion 10 are opposed to the placing surface 100 is determined by the control portion 51. In a case where it is determined at the step S7 that the changed state is the unused state, the control portion 51 advances to a step S8. At the step S8, the portable information display terminal 1 is shifted to the standby mode by the control portion 51, and the flow for change and maintenance of a display orientation corresponding to the state of the portable information display terminal 1 terminates. In a case where it is determined at the step S7 that the changed state is not the unused state, the control portion 51 advances to a step S9.

Thereafter, whether or not an application program corresponding to the changed state is set is determined by the control portion 51 at the step S9. In other words, whether or not an application program to be automatically started as to each of the stood state, the laid-down state, and the hand-held state is set by the user is determined at the step S9. In a case where it is determined at the step S9 that the application program corresponding to the changed state has not been set, the control portion 51 advances to the aforementioned step S4 and step S5, and the flow for change and maintenance of a display orientation corresponding to the state of the portable information display terminal 1 terminates. In a case where it is determined at the step S9 that the application program corresponding to the changed state has been set, the control portion 51 advances to a step S10.

At the step S10, whether or not the application program having been set is the same application program as a currently used application program is determined by the control portion 51. In a case where it is determined at the step S10 that the application program having been set is the same application program as the currently used application program, the application program may not be changed, and hence the control portion 51 advances to the aforementioned step S4 and step S5, and the flow for change and maintenance of a display orientation corresponding to the state of the portable information display terminal 1 terminates. In a case where it is determined at the step S10 that the application program having been set is not the same application program as the currently used application program, the control portion 51 advances to a step S11.

Thereafter, the application program, set by the user, corresponding to the changed state is started at the step S11, and the control portion 51 advances to a step S12. At the step S12, the display direction is changed to a display orientation corresponding to the state or the display orientation corresponding to the state is maintained, and the flow for change and maintenance of a display orientation corresponding to the state of the portable information display terminal 1 terminates. In a case where the state is changed from the laid-down state or the laterally held state of the hand-held state to the stood state, for example, the display orientation displayed on the liquid crystal display portion 10 is rotated by 180 degrees and changed. In a case where the state is changed from the vertically held state of the hand-held state or the stood state to the laid-down state, the display orientation displayed on the liquid crystal display portion 10 is rotated by 90 degrees or 270 degrees and changed. In a case where the state is changed from the laterally held state of the hand-held state to the laid-down state, the display orientation displayed on the liquid crystal display portion 10 is not changed but maintained as such.

The case where it is determined by the control portion 51 at the step S6 that the changed state is the hand-held state is now described in detail with reference to FIG. 14.

As shown in FIG. 14, in the case where it is determined at the step S6 (see FIG. 13) that the changed state is the hand-held state, the camera unit 11 is started by the control portion 51 at the step S21, and the control portion 51 advances to a step S22.

Thereafter, whether or not the orientation of the user's face has been able to be detected is determined by the control portion 51 on the basis of data imaged by the camera unit 11 at the step S22. In a case where it is determined at the step S22 that the orientation of the user's face has been able to be detected, the control portion 51 advances to a step S23. At the step S23, the direction of the screen display displayed on the liquid crystal display portion 10 is changed to a display direction corresponding to the orientation of the user's face or maintained by the control portion 51, and the flow for change and maintenance of a display orientation corresponding to the state of the portable information display terminal 1 terminates. In a case where the state is changed from the stood state to the laterally held state of the hand-held state, for example, the display orientation displayed on the liquid crystal display portion 10 is rotated by 180 degrees. In a case where the state is changed from the stood state, the laid-down state, or the laterally held state of the hand-held state to the vertically held state of the hand-held state, the display orientation displayed on the liquid crystal display portion 10 is rotated by 90 degrees or 270 degrees. In a case where the state is changed from the laid-down state to the laterally held state of the hand-held state, the display orientation displayed on the liquid crystal display portion 10 is not changed but maintained as such.

In a case where it is determined at the step S22 that the orientation of the user's face has not been able to be detected, the control portion 51 advances to a step S24. At the step S24, whether or not the detected inclination value has been changed through at least a prescribed angular range from a previously detected inclination value is determined by the control portion 51 on the basis of the inclination value detected by the inclination sensor 53. In other words, whether or not the user has moved the portable information display terminal 1 through a large angular range is determined. In a case where it is determined at the step S24 that the detected inclination value has been changed through less than the prescribed angular range from the previously detected inclination value, the control portion 51 advances to a step S25. At the step S25, the orientation of the screen display of the liquid crystal display portion 10 is not switched but the direction of the screen display currently displayed on the liquid crystal display portion 10 is maintained, and the flow for change and maintenance of a display orientation corresponding to the state of the portable information display terminal 1 terminates.

In a case where it is determined on the basis of the inclination value detected by the inclination sensor 53 at the step S24 that the detected inclination value has been changed through at least the prescribed angular range from the previously detected inclination value, the control portion 51 advances to a step S26. At the step S26, the orientation of the user's face is detected again by the control portion 51 with the face detection function.

Then, whether or not the orientation of the user's face has been able to be detected is determined again at a step S27. In a case where it is determined at the step S27 that the orientation of the user's face has been able to be detected, the control portion 51 advances to the aforementioned step S23. At the step S23, the screen display displayed on the liquid crystal display portion 10 is changed to a display direction corresponding to the orientation of the user's face or maintained, and the flow for change and maintenance of a display orientation corresponding to the state of the portable information display terminal 1 terminates.

In a case where it is determined at the step S27 that the orientation of the user's face has not been able to be detected, the control portion 51 advances to a step S28. At the step S28, the orientation of the screen display displayed on the liquid crystal display portion 10 is changed on the basis of the inclination value detected by the inclination sensor 53, and the flow for change and maintenance of a display orientation corresponding to the state of the portable information display terminal 1 terminates.

According to this embodiment, as hereinabove described, the orientation of the screen display of the liquid crystal display portion 10 is switched on the basis of the result of detection of the orientation of the user's face detected with the face detection function and the result of detection by the inclination sensor 53, whereby which state (attitude) the frame 20 is in can be detected by the inclination sensor 53 sensing the inclination of the frame 20 also in a case where the orientation of the user's face imaged by the camera unit 11 cannot be detected, dissimilarly to a case where the orientation of the screen display of the liquid crystal display portion 10 is switched on the basis of only the result of detection of the orientation of the user's face detected with the face detection function. Thus, the screen can be displayed in a suitable display orientation on the basis of the state (attitude) detected by the inclination sensor 53 also in the case where the orientation of the user's face imaged by the camera unit 11 cannot be detected.

According to this embodiment, as hereinabove described, the result of detection of the orientation of the user's face is prioritized over the use state detected by the inclination sensor 53 and the orientation of the screen display is switched to one corresponding to the orientation of the user's face in a case where the prescribed use state (hand-held state) is detected by the inclination sensor 53. Thus, the result of detection of the orientation of the user's face is prioritized in the case of the prescribed use state (hand-held state) where the orientation of the screen display based on the result of detection of the orientation of the user's face and the orientation of the screen display based on the inclination detected by the inclination sensor 53 easily differ from each other, so that the screen display can be displayed in an orientation more suitable to an actual use mode.

According to this embodiment, as hereinabove described, the result of detection of the orientation of the user's face is prioritized over the use state detected by the inclination sensor 53 and the orientation of the screen display is switched to one corresponding to the orientation of the user's face in a case where the use state (hand-held state) where the user uses the portable information display terminal 1 while grasping the frame 20 with his/her hand is detected. Thus, it is difficult to determine how the user sees the screen from the detection result based on the inclination detected by the inclination sensor 53 in a case where the user uses the portable information display terminal 1 while lying down in the state where the user grasps the frame 20 with his/her hand, and hence the screen display can be displayed in an orientation more suitable to an actual use mode by detecting the orientation of the user's face and switching the orientation of the screen display to one corresponding to the orientation of the user's face in the case where the portable information display terminal 1 is in the state where the user grasps the frame 20 with his/her hand.

According to this embodiment, as hereinabove described, the control of switching the orientation of the screen display of the liquid crystal display portion 10 is performed on the basis of the result of detection by the inclination sensor 53 in a case where the inclination sensor 53 detects that the portable information display terminal 1 is not in the use state (hand-held state) where the user uses the portable information display terminal 1 while grasping the frame 20 with his/her hand. In the case where the inclination sensor 53 detects that the user does not grasp the frame 20 with his/her hand as just described, the frame 20 is conceivably fixedly placed on the placing surface 100 or the like. In a case where the frame 20 is fixedly placed on the placing surface 100 or the like, the orientation of the liquid crystal display portion 10 and the orientation of the user's face when the user sees the liquid crystal display portion 10 satisfy a specific relationship, and the user's face can be detected less often than the case where the user uses the portable information display terminal 1 while grasping the frame 20 with his/her hand. Thus, in this case, the control of switching the orientation of the screen display of the liquid crystal display portion 10 is performed with the result of detection by the inclination sensor 53 without using the face detection function, whereby the screen can be displayed in a suitable display orientation.

According to this embodiment, as hereinabove described, the result of detection of the orientation of the user's face is prioritized and the orientation of the screen display of the liquid crystal display portion 10 is switched to the orientation of the screen display corresponding to the orientation of the user's face in a case where the inclination sensor 53 detects that the portable information display terminal 1 is at least in the hand-held state, while the orientation of the screen display of the liquid crystal display portion 10 is switched on the basis of the result of detection by the inclination sensor 53 in a case where the inclination sensor 53 detects that the portable information display terminal 1 is in the stood state or in the laid-down state, whereby the screen can be displayed in a suitable display orientation by the inclination sensor 53 in the case where the portable information display terminal 1 is in the stood state or the laid-down state where the frame 20 is placed on the placing surface 100. Furthermore, the screen can be displayed in a suitable display orientation matching the orientation of the user's face on the basis of the result of detection of the orientation of the user's face in the case where the portable information display terminal 1 is in the hand-held state where the user uses the portable information display terminal 1 while grasping the frame 20 with his/her hand.

According to this embodiment, as hereinabove described, the portable information display terminal 1 shifts to the standby mode without using the face detection function in a case where the inclination sensor 53 detects that the portable information display terminal 1 is not in the hand-held state where the user grasps the frame 20 and detects the inclination of the frame 20 in the unused state turning down the portable information display terminal so that the liquid crystal display portion 10 is opposed to the placing surface 100, while the portable information display terminal 1 does not shift to the standby mode but displays the screen display based on the result of detection of the orientation of the user's face on the liquid crystal display portion 10 in a case where the inclination sensor 53 detects that the portable information display terminal 1 is in the hand-held state and detects the inclination of the frame 20 in the unused state, whereby it is considered that the user does not use the portable information display terminal 1 in the case where the inclination sensor 53 detects that the portable information display terminal 1 is not in the hand-held state and detects the inclination of the frame 20 in the unused state. Thus, in this case, the portable information display terminal 1 shifts to the standby mode so that power consumption of the portable information display terminal 1 can be reduced. On the other hand, it is considered that the user uses the portable information display terminal 1 (sees the display portion while lying on his/her back, for example) in the case where the inclination sensor detects that the portable information display terminal 1 is in the hand-held state even when detecting the inclination of the frame 20 in the unused state, and hence in this case, the screen can be displayed in a suitable display orientation matching the orientation of the user's face on the basis of the result of detection of the orientation of the user's face.

According to this embodiment, as hereinabove described, the frame 20 is configured to have the outer shape settable on the placing surface 100 so that the inclination of the frame 20 in the stood state and the inclination of the frame 20 in the laid-down state become inclinations different from each other, whereby the frame 20 can be set on the placing surface 100 at different inclinations in the stood state and the laid-down state on the basis of the outer shape of the frame 20. Thus, the stood state and the laid-down state can be easily determined and specified on the basis of the result of detection by the inclination sensor 53, and the screen can be displayed in a suitable display orientation corresponding to the stood state or the laid-down state.

According to this embodiment, as hereinabove described, the orientation of the screen display of the liquid crystal display portion 10 is not switched but maintained if it is determined that an inclination value detected this time by the inclination sensor 53 falls within the prescribed angular range from an inclination value previously detected by the inclination sensor 53 in a case where the orientation of the user's face cannot be detected from the data of the user's face imaged by the camera unit 11, whereby the inclination value detected this time by the inclination sensor 53 has not been significantly changed from the inclination value previously detected by the inclination sensor 53 in the case where the inclination value detected this time by the inclination sensor 53 falls within the prescribed angular range from the inclination value previously detected by the inclination sensor 53 in the state where the user grasps the frame 20, and hence it is considered that a relative positional relationship between the user and the portable information display terminal 1 has not been significantly changed. In this case, the orientation of the screen display of the liquid crystal display portion 10 is not switched but maintained, whereby the screen can be displayed in a suitable display orientation matching the orientation of the user's face.

According to this embodiment, as hereinabove described, the orientation of the user's face is detected again with the face detection function of the camera unit 11 if it is detected that the inclination value detected this time by the inclination sensor 53 has been changed over the prescribed angular range from the inclination value previously detected by the inclination sensor 53 in a case where the orientation of the user's face cannot be detected from the data of the user's face imaged by the camera unit 11, whereby the inclination value detected this time by the inclination sensor 53 has been significantly changed from the inclination value previously detected by the inclination sensor 53 in the case where the inclination value detected this time by the inclination sensor 53 has been changed over the prescribed angular range from the inclination value previously detected by the inclination sensor 53 in the state where the user grasps the frame 20, and hence it is considered that the relative positional relationship between the user and the portable information display terminal 1 has been significantly changed or the way the user holds the frame 20 has been changed. In this case, the orientation of the user's face is detected again with the face detection function, whereby the screen can be displayed in a suitable display orientation matching the orientation of the user's face on the basis of a result of detection of the redetected orientation of the user's face.

The embodiment disclosed this time must be considered as illustrative in all points and not restrictive. The range of the present invention is shown not by the above description of the embodiment but by the scope of claims for patent, and all modifications within the meaning and range equivalent to the scope of claims for patent are included.

For example, while the example of detecting the orientation of the user's face with the face detection function only in the case where the portable information display terminal is in the hand-held state where the user uses the portable information display terminal while grasping the frame with his/her hand has been shown in the aforementioned embodiment, the present invention is not restricted to this. the orientation of the user's face may be detected with the face detection function also in a case where the portable information display terminal is in a state other than the hand-held state where the user uses the portable information display terminal while grasping the frame with his/her hand.

While the example of employing the inclination sensor as the example of the state detection sensor according to the present invention has been shown in the aforementioned embodiment, the present invention is not restricted to this. For example, a sensor other than the inclination sensor, such as an acceleration sensor may be employed to detect the state of the portable information display terminal.

While such an example that the inclination sensor detects only any of the stood state where the user uses the portable information display terminal while standing the frame and the liquid crystal display portion on the placing surface, the laid-down state where the user uses the portable information display terminal while laying down the frame and the liquid crystal display portion on the placing surface, the hand-held state where the user uses the portable information display terminal while grasping the frame with his/her hand, and the unused state where the user turns down the portable information display terminal so that the frame and the liquid crystal display portion are opposed to the placing surface has been shown in the aforementioned embodiment, the present invention is not restricted to this. The state detection sensor may detect a state other than the stood state, the laid-down state, the hand-held state, and the unused state such as that where the user uses the portable information display terminal while hanging the same on a wall surface, in addition to the stood state, the laid-down state, the hand-held state, and the unused state, for example.

While the example of configuring the frame in the outer shape placeable in the stood state where the user uses the portable information display terminal while standing the frame and the liquid crystal display portion on the placing surface and the laid-down state where the user uses the portable information display terminal while laying down the frame and the liquid crystal display portion on the placing surface has been shown in the aforementioned embodiment, the present invention is not restricted to this. A stand or the like of a separate member may be so mounted on the frame (housing) that the frame is placed in the stood state where the user uses the portable information display terminal while standing the frame and the liquid crystal display portion on the placing surface and the laid-down state where the user uses the portable information display terminal while laying down the frame and the liquid crystal display portion on the placing surface.

While the example of performing remote control of the control object apparatus by emitting the infrared rays including the remote control signal to the control object apparatus in the remote control mode has been shown in the aforementioned embodiment, the present invention is not restricted to this. The control object apparatus may be remote-controlled by employing a wireless communication standard such as Bluetooth (registered trademark) or Zigbee (registered trademark), for example.

While processing operations of the control portion have been described by employing the flow charts described in an event-driven manner in starting and described in a flow-driven manner as to processing operations after the starting for the convenience of illustration in the aforementioned embodiment, the present invention is not restricted to this. The processing operations of the control portion may be performed in a complete event-driven manner, in a complete flow-driven manner, or in a parallel processing manner.

What is claimed is:

1. A portable information display terminal comprising:
a display portion displaying information;
a housing provided with said display portion on a surface thereof;
a state detection sensor to detect at least a use state of said housing and said display portion by sensing an inclination of said housing;
an imaging portion capable of imaging a user's face; and
a control portion detecting an orientation of the face with a face detection function on the basis of data of the user's face imaged by said imaging portion and performing control of switching an orientation of a screen display of said display portion on the basis of a result of detection of the orientation of the face and a result of detection by said state detection sensor.

2. The portable information display terminal according to claim 1, wherein
said control portion is configured to prioritize said result of detection of the orientation of the user's face over the use state detected by said state detection sensor and switch the orientation of the screen display to one corresponding to the orientation of the user's face in a case where said state detection sensor detects a prescribed use state.

3. The portable information display terminal according to claim 2, wherein
said prescribed use state is a use state where the user uses the portable information display terminal while grasping said housing with his/her hand, and
said control portion is configured to prioritize said result of detection of the orientation of the user's face over the use state detected by said state detection sensor and switch the orientation of the screen display to one corresponding to the orientation of the user's face in a case where said use state where the user uses the portable information display terminal while grasping said housing with his/her hand is detected.

4. The portable information display terminal according to claim 3, wherein
said control portion is configured to perform control of switching the orientation of the screen display of said display portion on the basis of said result of detection by said state detection sensor in a case where said state detection sensor detects that the portable information display terminal is not in said use state where the user uses the portable information display terminal while grasping said housing with his/her hand.

5. The portable information display terminal according to claim 2, wherein
said state detection sensor is provided to detect which use state of a first use state where the user uses the portable information display terminal while standing said housing and said display portion on a placing surface, a second use state where the user uses the portable information display terminal while laying down said housing and said display portion on the placing surface, and a third use state where the user uses the portable information display terminal while grasping said housing with his/her hand as said prescribed use state the portable information display terminal is in by sensing the inclination of said housing, and
said control portion is configured to perform control of prioritizing said result of detection of the orientation of the user's face and switching the orientation of the screen display to one corresponding to the orientation of the user's face in a case where said state detection sensor detects that the portable information display terminal is at least in said third use state, and to perform control of switching the orientation of the screen display of said display portion on the basis of said result of detection by said state detection sensor in a case where said state detection sensor detects that the portable information display terminal is in said first use state or said second use state.

6. The portable information display terminal according to claim 2, wherein
said state detection sensor is configured to detect at least an unused state turning down the portable information display terminal so that said display portion is opposed to a placing surface in addition to said prescribed use state, and
said control portion is configured to perform control of shifting to a standby mode without using said face detection function in a case where said state detection sensor detects that the portable information display terminal is not in said prescribed use state where said housing is grasped by the user and detects an inclination of said housing in said unused state turning down the portable information display terminal so that said display portion is opposed to the placing surface, and to perform control of not shifting to said standby mode but displaying a screen display based on said result of detection of the orientation of the user's face on said display portion in a case where said state detection sensor detects that the portable information display terminal is in said prescribed use state where said housing is grasped by the user and detects the inclination of said housing in said unused state turning down the portable information display terminal so that said display portion is opposed to the placing surface.

7. The portable information display terminal according to claim 2, wherein
said state detection sensor is provided to detect which use state of a first use state where the user uses the portable information display terminal while standing at least said housing and said display portion on a placing surface, a second use state where the user uses the portable information display terminal while laying down said housing and said display portion on the placing surface, and a third use state where the user uses the portable information display terminal while grasping said housing with his/her hand as said prescribed use state the portable information display terminal is in by sensing the inclination of said housing, and
said housing is configured to have an outer shape settable on the placing surface so that a first inclination of said housing in said first use state and a second inclination of said housing in said second use state become inclinations different from each other.

8. The portable information display terminal according to claim 1, wherein
said control portion is configured to maintain the orientation of the screen display of said display portion unswitched if determining that an inclination value detected this time by said state detection sensor falls within a prescribed angular range from an inclination value previously detected by said state detection sensor in a case where the orientation of the user's face cannot be detected from the data of the user's face imaged by said imaging portion when said state detection sensor detects a use state where the user uses the portable information display terminal while grasping said housing with his/her hand.

9. The portable information display terminal according to claim 8, wherein
said control portion is configured to detect the orientation of the user's face again with said face detection function if it is detected that the inclination value detected this time by said state detection sensor has been changed over the prescribed angular range from the inclination value previously detected by said state detection sensor in the case where the orientation of the user's face cannot be detected from the data of the user's face imaged by said imaging portion.

10. The portable information display terminal according to claim 1, wherein
said state detection sensor includes an inclination sensor.
